(19) United States
(12) Patent Application Publication
(10) Pub. No.: US 2013/0154454 A1
(43) Pub. Date: Jun. 20, 2013

(54) MACHINE BOX STRUCTURE CAPABLE OF LOADING MULTIPLE SYSTEMS

(71) Applicant: Tang-Hsien Huang, Taipei City (TW)

(72) Inventor: Tang-Hsien Huang, Taipei City (TW)

(73) Assignee: MULTI-EXPANDER TECHNOLOGY INC., New Taipei City (TW)

(21) Appl. No.: 13/412,240

(22) Filed: Mar. 5, 2012

(30) Foreign Application Priority Data
Dec. 20, 2011 (TW) 100224060

(51) Int. Cl. H05K 5/02

(52) U.S. Cl. 312/223.2; 312/223.1

(57) ABSTRACT

A machine box structure capable of loading multiple systems includes a main casing that is a hollow casing in which two ends have openings, at least one partition member further configured in the opening to divide the opening into a plurality of removable slots; and a plurality of system loading boxes that are a casing in which its shape corresponds to the removable slot removably passing through the removable slot, and the system loading box having a system configuration space therein.

### CROSS-REFERENCE TO RELATED APPLICATION

This application claims the benefit under 35 U.S.C. §119 of Taiwan Patent Application No. 100224060, filed Dec. 20, 2011, which is incorporated herein by reference in its entirety.

### BACKGROUND OF THE INVENTION

1. Field of the Invention

The present invention relates to a machine box structure capable of loading multiple systems, and more particularly to a machine box having better space to simultaneously load at least two systems.

2. Description of the Related Art

Since electronic technology is gradually developed and advanced and work culture is changed, current units, such as companies or factories, laboratories, aggressively introduce e-work to replace manual works performed by labor force under past conventional work state. Therefore, utilizing a system host to provide an operating system in the work place where operating personnels work becomes a usual circumstance.

In the current technique, the system host depicted in the foregoing sentences usually takes larger spaces. Further, since the type of system host is also important, the host must be stored in an independent space. Consequently, space configuration for work and operating environment may not be easily achieved. The plurality of system hosts must be applied to achieve work requirement to cause inconvenience in space utilization. In fact, properly designing a casing of the system host may reduce the foregoing defects. However, the design may not be easily seen in markets. Designing a machine box structure capable of loading multiple systems can improve the shortcomings of the conventional technique to increase industrial application.

### BRIEF SUMMARY

In view of the shortcomings of the prior art, the inventor(s) of the present invention based on years of experience in the related industry to conduct extensive researches and experiments, and finally developed a machine box structure capable of loading multiple systems as a principle objective to overcome the difficulty of prior arts.

To achieve the foregoing objective of the invention, a machine box structure capable of loading multiple systems is designed by a technique manner adopted by the invention and includes: a main casing that is a hollow casing in which two ends of the hollow casing has openings, the opening further disposed with at least one partition member for dividing the opening into a plurality of removable slots; and a plurality of system loading boxes that is a casing in which its shape corresponds to the removable slot correspondingly passing through the removable slot, and a system configuration space configured in the system loading box.

Wherein quantity of the removable slot and quantity of the system loading boxes both are two. The configuration of the system configuration space comprises a hard disk loading space disposed corresponding to a front side of the main casing. A plurality of hard disc loading slots that are horizontally configured are disposed in the hard disc loading space. A rear side of the system configuration space corresponding to the main casing is disposed with a motherboard configuration space and a power supply area. The power supply area is correspondingly disposed to a side of the motherboard configuration space. The power supply area is a rectangular space to further configure a rectangular power supply. The removable slot is an elongated shape, and the main casing is a flat rectangle or a square.

The machine box structure capable of loading multiple systems according to the invention utilizes structure incorporation to vertically configure at least two system configuration spaces in a thin-shape main casing having less height. By correspondingly utilizing accessories without height, a purpose of effectively thinning the whole system host can be achieved to further provide a loading machine box with the minimum space occupation in a work space that needs a plurality of operating system hosts, thereby specifically reducing the problem of space configuration. In addition, with a concept of one-machine-casing and multiple-system, the expense of installing racks spent by a user or an entrepreneur can be further saved.

### BRIEF DESCRIPTION OF THE DRAWINGS

FIG. 1 is a schematic diagram of a machine box structure capable of loading multiple systems according to the invention;

FIG. 2 is a decomposition drawing of a machine box structure capable of loading multiple systems according to the invention;

FIG. 3 is a front view of a machine box structure capable of loading multiple systems according to the invention;

FIG. 4 is a configuration schematic diagram of a machine box structure capable of loading multiple systems according to the invention;

### DETAILED DESCRIPTION

The foregoing and other technical characteristics of the present invention will become apparent with the detailed description of the preferred embodiments and the illustration of the related drawings.

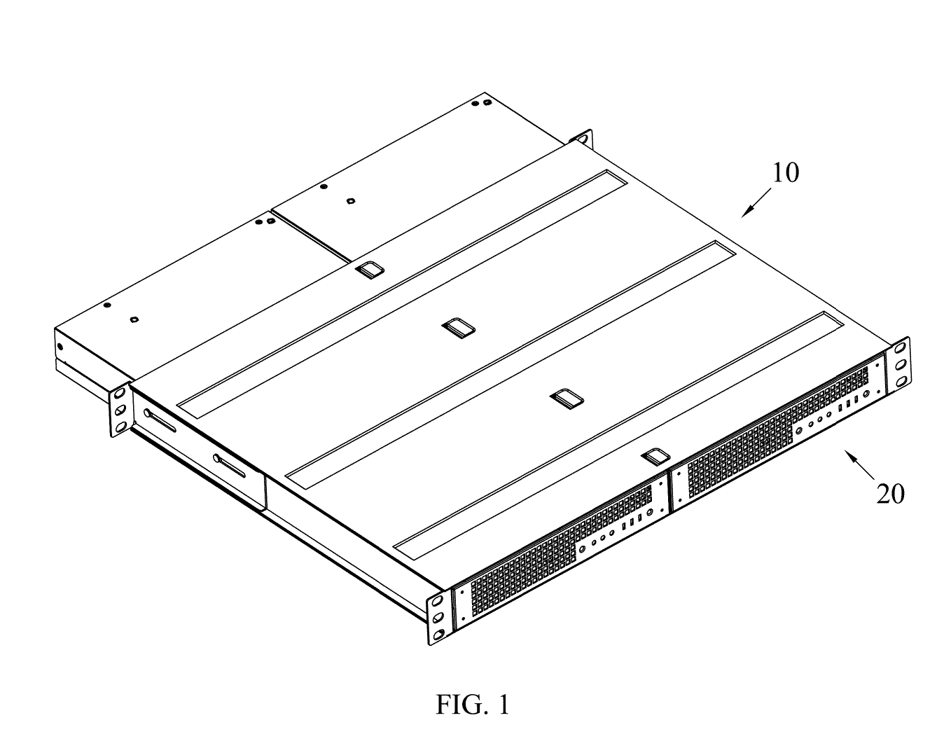

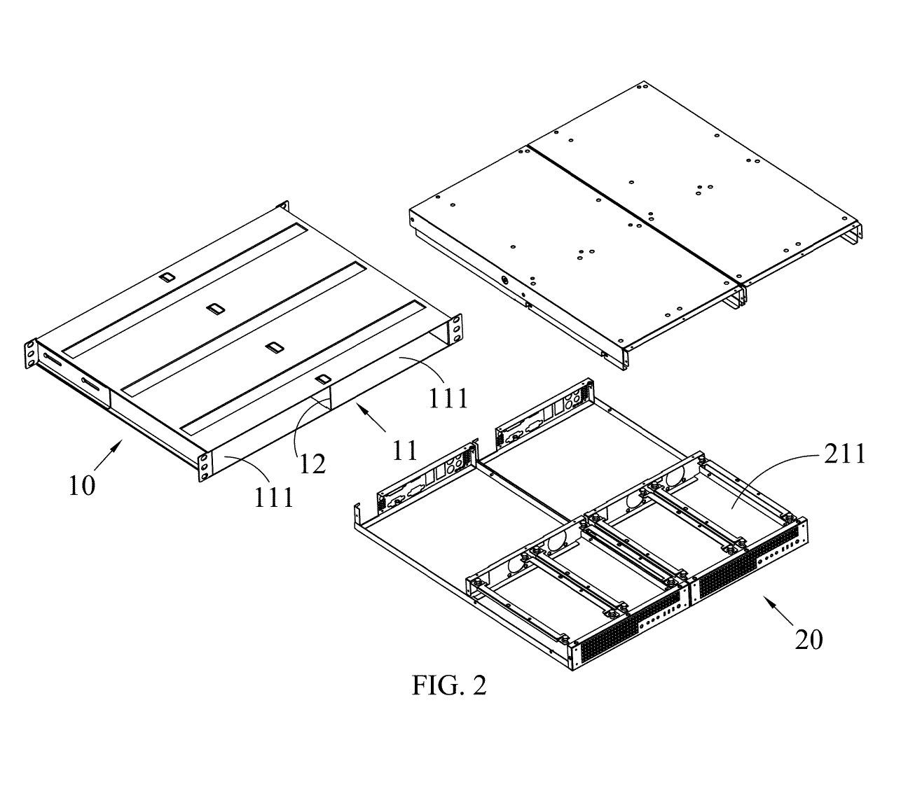

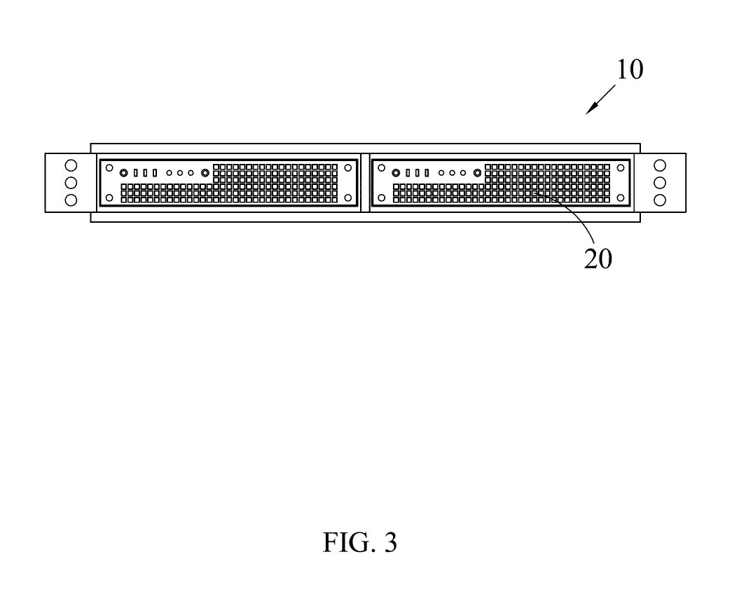

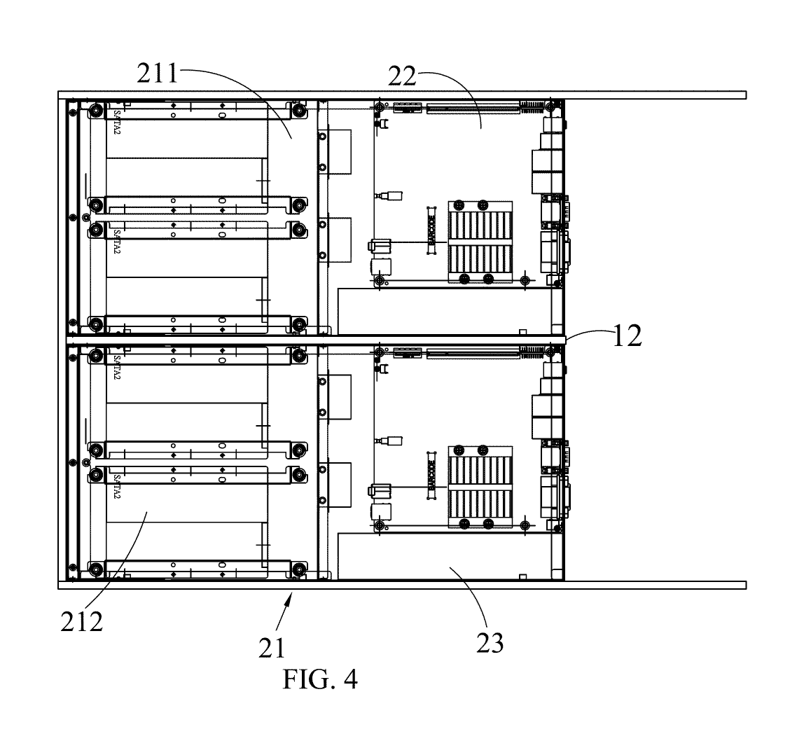

With reference to FIG. 1 to FIG. 4, the invention provides a machine box structure capable of loading multiple systems, wherein a preferable embodiment can include a main casing 10 and a plurality of system loading boxes 20.

The main casing 10 is a flat long rectangular or square hollow casing in which two ends of the main casing have openings 11, and at least one partition member 12 is disposed in the opening 11 to divide the opening 11 into a plurality of removable slots 111. The removable slots 111 are rectangles.

The system loading box 20 is a casing, wherein its shape corresponds to the removable slots 111 to be correspondingly removed from and disposed in the removable slots 111, and a system configuration space 21 is disposed in the system loading box 20. According to the configuration of the system configuration space 21, a hard disc loading space 211 is disposed to a front side of system configuration corresponding to the main casing 10. A plurality of hard disc slots 212 that is horizontally disposed is fixed in the hard disc loading space 211 to fix and dispose a plurality of hard discs in the hard disc loading space 211.

Moreover, a rear place of the system configuration space 211 corresponding to the main casing 10 is disposed with a motherboard configuration space 22 and a power supply area 23, wherein a circuit board that can be horizontally configured is locked in the motherboard configuration space 22 to insert cables of network cable, a monitor cable, a keyboard cable and a mouse cable. The power supply area 23 is correspondingly disposed to a side of the motherboard configuration space 22 and is a rectangular space such that a rectangular power supplier can be configured in the power supply area 23.

The machine box structure capable of loading multiple systems can be designed with variety. By incorporating with the structure, at least two system loading boxes 20 are vertically configured in the main casing 10 having a thin shape without height to further have at least two system configuration spaces 21. By relatively utilizing accessories having no height, the purpose of effectively thinning the whole system host can be achieved such that a loading machine box with the lowest space occupation is provided in a work space that needs the plurality of operating system hosts to specifically reduce the problem of space configuration. In addition, with a concept of one-machine-casing and multiple-system, the expense of installing racks spent by a user or an entrepreneur can be further saved. In actual application, a high degree of convenience can also be provided. If a single system malfunctions, maintenance can be performed by removing the system loading box 20. Thus, it may not have the problem of all of the multiple systems in the main casing 10 requiring to be sent for maintenance simultaneously to overcome prior arts.

The invention improves over the prior art and complies with patent application requirements, and thus is duly filed for patent application. While the invention has been described by device of specific embodiments, numerous modifications and variations could be made thereto by those generally skilled in the art without departing from the scope and spirit of the invention set forth in the claims.

What is claimed is:

1. A machine box structure capable of loading multiple systems comprising:
a main casing being a hollow casing in which two ends of the hollow casing has openings, the opening further disposed with at least one partition member for dividing the opening into a plurality of removable slots; and
a plurality of system loading boxes being a casing in which a shape of the casing corresponds to the removable slot correspondingly passing through the removable slot, and a system configuration space configured in the system loading box.

2. The machine box structure capable of loading multiple systems as recited in claim 1, wherein quantity of the removable slots and quantity of the system loading boxes both are two.

3. The machine box structure capable of loading multiple systems as recited in claim 2, wherein a configuration of the system configuration space comprises a hard disc loading space disposed corresponding to a front side of the main casing.

4. The machine box structure capable of loading multiple systems as recited in claim 3, wherein a plurality of hard disc slots that is horizontally configured is disposed in the hard disc loading space.

5. The machine box structure capable of loading multiple systems as recited in claim 3, wherein a rear side of the system configuration space corresponding to the main casing is disposed with a motherboard configuration space and a power supply area.

6. The machine box structure capable of loading multiple systems as recited in claim 5, wherein a circuit board that is horizontally configured is disposed in the motherboard configuration space.

7. The machine box structure capable of loading multiple systems as recited in claim 6, wherein the power supply area is correspondingly disposed to a side of the motherboard configuration space.

8. The machine box structure capable of loading multiple systems as recited in claim 7, wherein the power supply area is a rectangular space to further configure a rectangular power supply.

9. The machine box structure capable of loading multiple systems as recited in claim 8, wherein the removable slot is an elongated shape.

10. The machine box structure capable of loading multiple systems as recited in claim 8, wherein the main casing is a flat rectangle or a square.
